(19) United States
(12) Patent Application Publication
(10) Pub. No.: US 2007/0114601 A1
(43) Pub. Date: May 24, 2007

(54) Gate contact structure for a power device

(76) Inventors: Wei-Jye Lin, Chaujou Township (TW); Ming-Jang Lin, Hsinchu City (TW); Chorng-Wei Liaw, Zhubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/521,548

(22) Filed: Sep. 15, 2006

(30) Foreign Application Priority Data
Nov. 22, 2005 (TW) 094140997

(51) Int. Cl. H01L 29/94

(52) U.S. Cl. 257/330

(57) ABSTRACT

A gate contact structure for a power device comprises a substrate having a trench, a gate conductor in the trench and striding over a side of the trench, a first insulator between the gate conductor and the trench, a second insulator covering the gate conductor, a contact window in the second insulator above the trench and striding the side of the trench to expose a surface of the underlying gate conductor, and a gate metal electrically contacting the gate conductor through the contact window.

### FIELD OF THE INVENTION

The present invention is related generally to a semiconductor device and, more particularly, to a gate contact structure for a power device.

### BACKGROUND OF THE INVENTION

In a power device, a gate polysilicon within a trench in a source region is connected to a gate metal on the periphery by a gate contact structure and thus a gate current flows from the gate metal into the gate polysilicon within the trench to active the power device. FIG. 1 shows a typical layout of a conventional power device, and FIG. 2 shows a cross-sectional view of a gate contact structure of the conventional power device shown in FIG. 1 along the AA′ direction. As shown in FIG. 1 and FIG. 2, there is a gate region 110 located outside of a source region 120, a trench 130 is located within the source region 120, and a contact window 140 is located within the gate region 110. When a gate current 180 flows from a gate metal 160 to a gate polysilicon 150 through the contact window 140, it must flow through the region 170 before reaching the portion of the gate polysilicon 150 within the trench 130. Due to the region 170 of the gate polysilicon 150, limiting the gate current 180 to flow within specific height and width, and the resistance of the gate polysilicon 150 greater than that of the gate metal 160 to cause the gate current 180 flowing through a quite large series resistor, the turn on speed of the power device degrades. Moreover, the height and width of the region 170 are reduced with the decreasing scale of the device, thereby increasing the series resistor resulted from thereof, which also has the region 170 to withstand higher voltage and be damaged easily.

To improve the power device, U.S. Pat. No. 5,597,765 to Yilmaz et al. discloses a termination structure located along a transistor peripheral or a die edge for a power MOSFET as shown in FIG. 3 to reduce or eliminate the channeling phenomena, U.S. Pat. No. 5,904,525 discloses a fabrication of high-density trench double-diffused MOS using sidewall spacers as shown in FIG. 4, U.S. Pat. No. 6,620,691 discloses a semiconductor trench device with enhanced gate oxide integrity structure as shown in FIG. 5 to improve the breakdown voltage of the oxide layer, and U.S. Pat. No. 6,861,701 discloses a trench power MOSFET with planarized gate bus as shown in FIG. 6. However, these arts all have a region 210 that causes a large series resistor and thereby cannot enhance the performance of the power device. For resolving the problem of the large series resistor, it is proposed a structure without the region 210 as shown in FIG. 7, which comprises a substrate 310 having a trench 320, a gate polysilicon 340 in the trench 320, an insulator 330 covering the gate polysilicon 340, a contact window 360 in the insulator 330 above the trench 320, and a gate metal 350 electrically contacting the gate polysilicon 340 through the contact window 360. Although such structure can resolve the problem of the large series resistor, it is hard to align the contact window 360 to the trench 320 in the lithographic process since the trench 320 is not large, and it is easy to damage the gate polysilicon 340 in the trench 320 in the etching process, which cause the manufacturing processes hard to control.

Therefore, it is desired a gate contact structure for a power device to resolve the problem of the large series resistor and the manufacturing process control.

### SUMMARY OF THE INVENTION

An object of the present invention is to provide a gate contact structure for a power device.

According to the present invention, a gate contact structure for a power device comprises a substrate having a trench, a gate conductor in the trench and striding over a side of the trench, a first insulator between the gate conductor and the trench, a second insulator covering the gate conductor, a contact window in the second insulator for exposing a surface of the gate conductor which strides over the side of the trench, and a gate metal electrically contacting the gate conductor through the contact window.

By using the gate conductor and the contact window both striding over the side of the trench, a gate current can vertically flow from the gate metal in the contact window to the gate conductor in the trench to avoid the gate current to laterally flow along the gate conductor in order to reduce the series resistor.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a typical layout of a conventional power device;

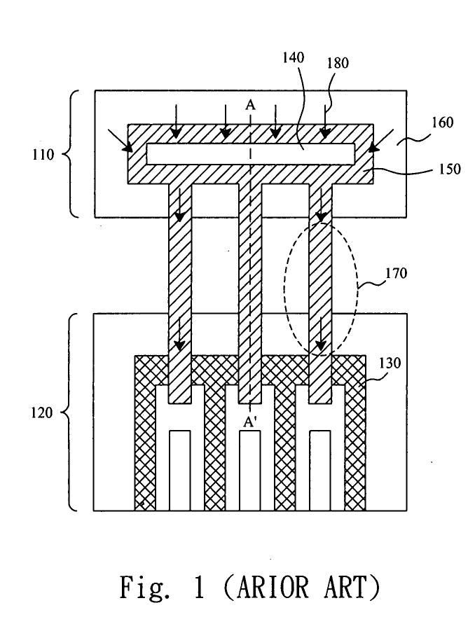

FIG. 2 shows a cross-sectional view of a gate contact structure of the conventional power device shown in FIG. 1 along the AA′ direction;

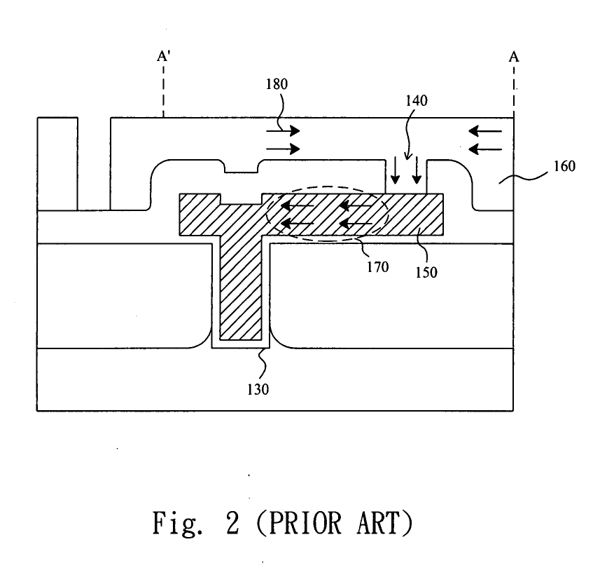

FIG. 3 shows a cross-sectional view of a conventional power device;

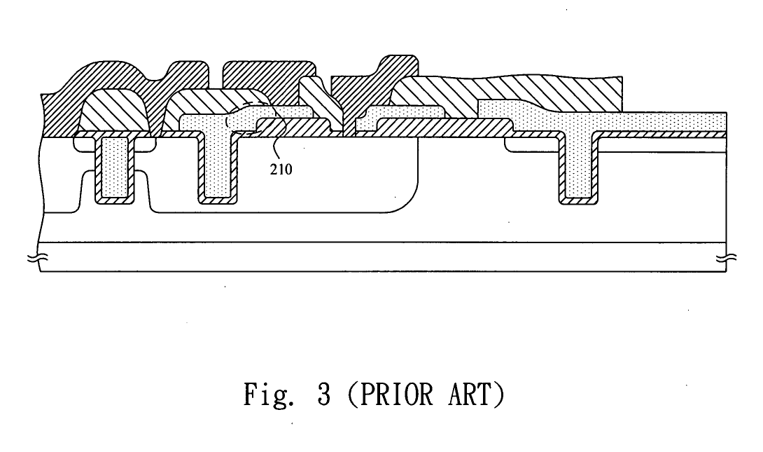

FIG. 4 shows a cross-sectional view of a conventional power device;

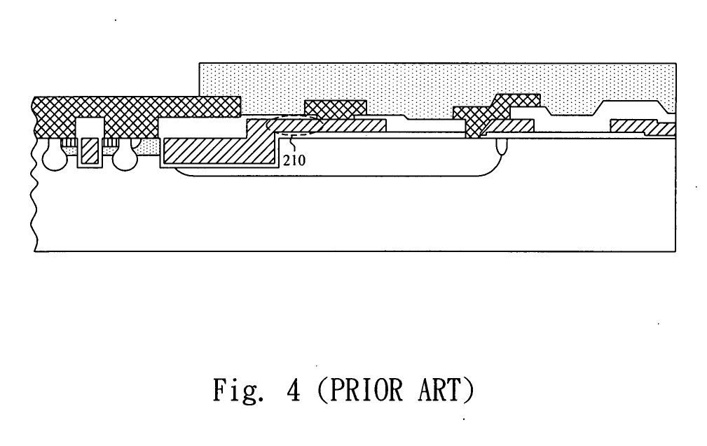

FIG. 5 shows a cross-sectional view of a conventional power device;

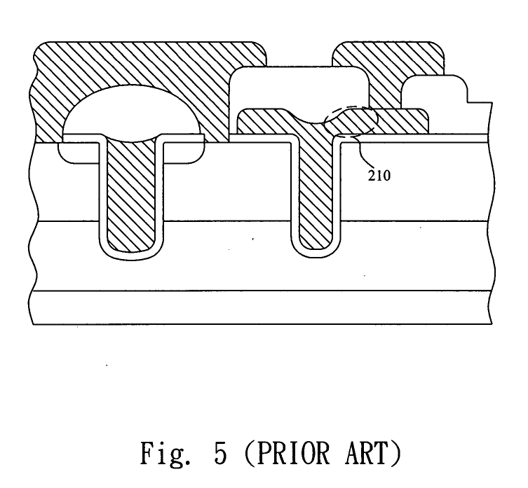

FIG. 6 shows a cross-sectional view of a conventional power device;

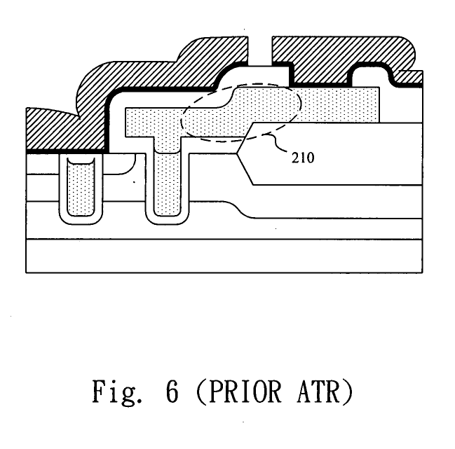

FIG. 7 shows a cross-sectional view of a gate contact structure of a conventional power device;

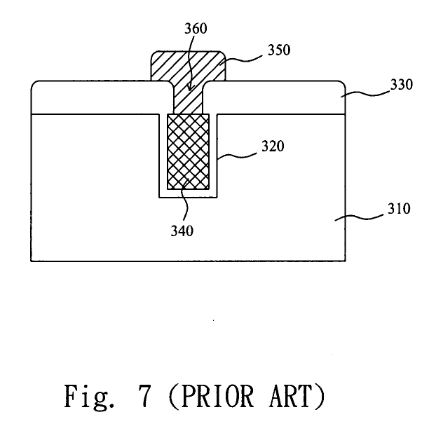

FIG. 8 shows a layout of a power device according to the present invention; and

FIG. 9 shows a cross-sectional view of a gate contact structure of the power device shown in FIG. 8 along the AA′ direction.

### DETAILED DESCRIPTION OF THE INVENTION

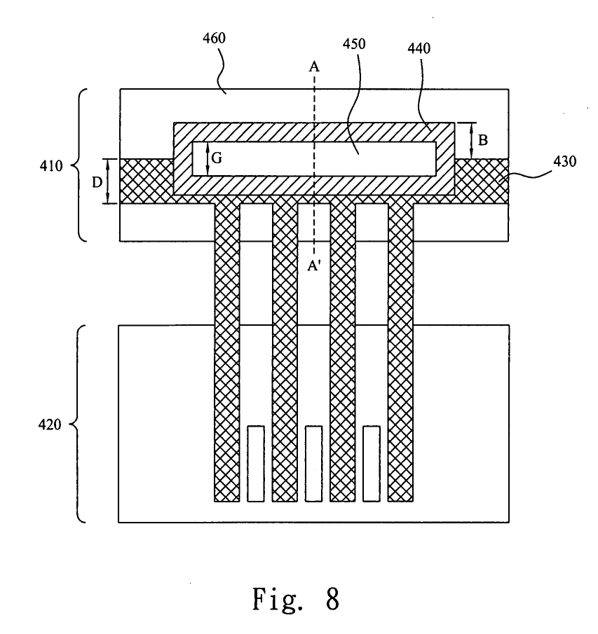

FIG. 8 shows a layout of a power device according to the present invention, in which a gate region 410 is located outside of a source region 420, and in the gate region 410, a trench 430 is overlapped by a portion of a contact window 450 and a portion of a gate conductor 440. The gate conductor 440 and the contact window 450 both stride over one side of the trench 430 that is far away from the source region 420. When a gate current flows from a gate metal 460 to the gate conductor 440 through the contact window 450, it will vertically flow into the gate conductor 440 within the trench 430 and enter the source region 420, thereby reducing the series resistor resulted if the current laterally flows through the gate conductor 440. In addition, the gate conductor 440 has a portion striding over the side of the trench 430 far away from the source region 420, and therefore it is reduced the size of the power device and increased the density of the power devices in manufacture.

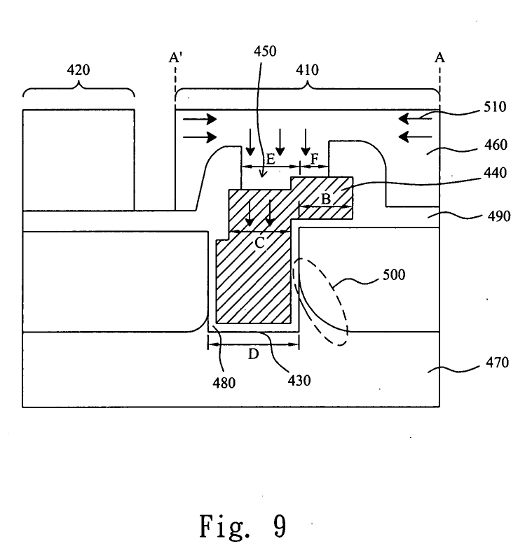

FIG. 9 is a cross-sectional view of the gate contact structure of the power device shown in FIG. 8 along the AA′ direction. A substrate 470 includes the gate region 410 and the source region 420, and in the gate region 410, an insulator 480 (such as a silicon dioxide) is located on the bottom and sidewalls of the trench 430. The gate conductor 440 (such as a polysilicon) is located in the trench 430 and strides over the side of the trench 430 that is far away from the source region 420. The width C of the gate conductor 440 at the opening of the trench 430 is smaller than the width D of the trench 430. An insulator 490 (such as a silicon dioxide) covers the gate conductor 440, and the contact window 450 is formed in the insulator 490 such that it has a portion above the trench 430 and strides over the one side of the trench 430 that is far away from the source region 420. The width E of the portion of the contact window 450 above the trench 430 is smaller than the width C of the gate conductor 440 at the opening of the trench 430, and the width F of the portion of the contact window 450 above the gate conductor 440 striding over the side of the trench 430 that is far away from the source region 420 is smaller than the length B of the gate conductor 440 striding over the side of the trench 430 that is far away from the source region 420. The gate metal 460 electrically connects to the gate conductor 440 through the contact window 450. When a gate current 510 flows from the gate metal 460 into the gate conductor 440 through the contact window 450, it will vertically flow into the gate conductor 440 within the trench 430, thereby reducing the series resistor resulted if the gate current 510 laterally flows through the gate conductor 440. As a result, the performance of the power device is improved. In addition, the length B of the gate conductor 440 striding over the side of the trench 430 that is far away from the source region 420 is so short that the ion implant can diffuse under the gate conductor 440 to reach the edge of the trench 430, as shown in region 500. Thus, this structure of the present invention can be implemented by the current semiconductor processes with the same number of masks by altering the layout design without adding more process steps or altering the processes. Preferable, the length B is 0.5 μm, the width D is 1.1 μm, and the width G (G=E+F) of the contact window 450 is 0.7 μm.

In the situation of without altering the processes, the present invention achieves the goals of reducing the series resistor of the power device, making the processes control easier, and being applicable to all types of trench power devices, for example, trench power MOSFET and insulated gate bipolar transistor (IGBT).

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A gate contact structure for a power device, comprising:
a substrate having a trench;
a gate conductor having a first portion in said trench and a second portion striding over a side of said trench;
a first insulator between said gate conductor and said trench;
a second insulator covering said gate conductor;
a contact window in said second insulator, having a first portion above said trench and a second portion striding over said side of said trench, for exposing a surface of said gate conductor; and
a gate metal electrically contacting said gate conductor through said contact window.

2. The gate contact structure of claim 1, wherein said first portion of said gate conductor has a width at an opening of said trench smaller than a width of said trench.

3. The gate contact structure of claim 1, wherein said second portion of said gate conductor striding over said side of said trench has a length so short that an ion implant can diffuse under said second portion of said gate conductor striding over said side of said trench to reach an edge of said trench.

4. The gate contact structure of claim 1, wherein said second portion of said contact window striding over said side of said trench has a width smaller than a length of said second portion of said gate conductor striding over said side of said trench.

5. The gate contact structure of claim 1, wherein said first portion of said contact window above said trench has a width smaller than a width of said second portion of said gate conductor above said trench.

6. The gate contact structure of claim 1, wherein said first insulator comprises a silicon dioxide.

7. The gate contact structure of claim 1, wherein said gate conductor comprises a gate polysilicon.

8. The gate contact structure of claim 1, wherein said second insulator comprises a silicon dioxide.
